(19) United States
(12) Patent Application Publication
(10) Pub. No.: US 2012/0025217 A1
(43) Pub. Date: Feb. 2, 2012

(54) LED LIGHTING MODULE

(76) Inventors: Tek Beng LOW, Melaka (MY); Eng Wah TAN, Melaka (MY)

(21) Appl. No.: 13/193,873

(22) Filed: Jul. 29, 2011

(30) Foreign Application Priority Data
Jul. 30, 2010 (MY) PI 2010003632

(51) Int. Cl. H01L 33/52

(52) U.S. Cl. 257/88; 257/E33.059

(57) ABSTRACT

The invention relates to a light emitting diode (LED) module that is characterized by a thermally conductive substrate which is used as the base of the module; a plurality of cavities positioned on the module; each cavity is filled with a transparent or diffused encapsulant material and a plurality of LED semiconductors chips are mounted within each cavity.

### FIELD OF INVENTION

The invention relates to a light emitting diode (LED) module that can be used for general lighting applications, back-lighting and signage. The module is characterized by a thermally conductive substrate which is used as the base of the module; a plurality of cavities positioned on the module; each cavity is filled with a transparent or diffused encapsulant material and a plurality of LED semiconductors chips are mounted within each cavity.

### PRIOR ART

Optoelectronic components such as LED are widely used in the world today especially for lighting and signaling applications. Conventionally, LED semiconductors chips are first packaged within a housing to form a component. The housing typically consists of a metal lead-frame which is used as the base to attach the chip. Electrically conducting wires are then bonded to connect the chip to the lead-frame terminals. A transparent or diffused encapsulant is then molded onto the assembly to form the complete housing. This housing provide the necessary protection for the semiconductor chip from the environment and enable the part to be subsequently soldered onto printed circuits boards using conventional surface mounting technology. FIG. 1 show how a typical LED light bar can be constructed using LED components which were mounted and soldered onto a printed circuit board (PCB).

Alternatively, there is another approach where a component is not used. LED semiconductor chips are directly attached onto a PCB. Electrically conductive wires are used to connect the chips onto the circuit printed on the PCB. Encapsulant material with high viscosity is then potted onto the chips and wires as a means to protect the assembly. This approach is commonly known as the chip on board technique (COB).

An example of such COB technique is as described WO 02/05351. The prior art described the method where several LEDs without housings are mounted onto a printed circuit board and the LEDs are potted using a highly transparent polymer. A reflector is then placed on the printed circuit board from above around each LED. The diameter of the potting compound is at least equal to the internal diameter of the reflectors in such a way that the reflectors lies in direct contact with the printed circuit board and the surface of the potting compound is configured as an optically active lens surface.

However, this method has its disadvantages. It is typically costly and difficult to produce a potting which can be configured as an optically active lens surface. The profile of the potting may vary from lens to lens and this will affect the optical characteristics. In addition, an optimum reflector design is critical in such design in order to match with the potted lens and ensure that light is efficiently extracted from the LEDs and projected to the required direction.

This patent will try to describe an alternative method that will simplify the construction but yet ensure good reliability and efficient extraction of light from the LED chips.

### DESCRIPTION OF DRAWINGS

The drawings enclosed are as follows:

FIG. 1 illustrates a typical LED light bar constructed using LED components which were mounted and soldered onto a printed circuit board (PCB);

FIG. 2 illustrates the cross section view of a typical construction described by the present invention;

FIG. 3 illustrates the first embodiment of the present invention;

FIG. 4 illustrates an enlarged view of the first embodiment of the present invention;

FIG. 5 illustrates the second embodiment of the present invention;

FIG. 6 illustrates the third embodiment of the present invention;

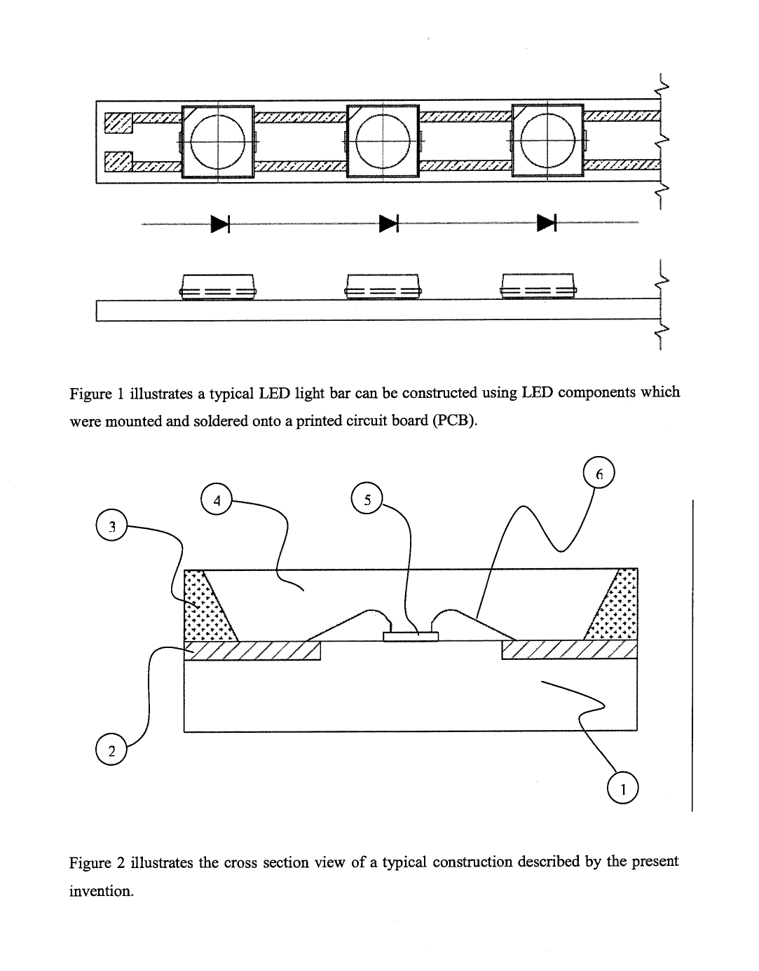

### DETAIL DESCRIPTION

The invention relates to a light emitting diode (LED) module that is characterized by a thermally conductive substrate which is used as the base of the module; a plurality of cavities positioned on the module; each cavity is filled with a transparent or diffused encapsulant material and a plurality of LED semiconductors chips are mounted within each cavity.

In accordance to the present invention, a thermally conductive substrate is used as the base of the module. Typical materials that can be used include metals such as aluminum, copper and other forms of copper alloy. Besides that, non-metals such as ceramic, AlN and hybrid BT resin with enhanced thermal via can also be used as the substrate. The key property required is high thermal conductivity. This thermally conductive substrate will serve as the heat-sink for the module besides providing the base for the module. When this substrate surface is mounted onto a larger secondary surface, heat can be more effectively dissipated away. In some instance, this substrate can be extended in size to allow for a bigger surface area for contact and better thermal dissipation. This substrate can also be used as a mechanical interface surface since the substrate is rigid in nature and mechanically strong. Locating holes or mounting holes can be designed on this substrate for this purpose. In case of metal substrate, the extended substrate can also be formed and bent to facilitate further flexibility in design or to accommodate design needs for mounting.

On top of the thermally conductive substrate, an electrical isolated and thin material is laminated or attached on a portion of the substrate. This electrically isolated material will provide the plane for electrical traces and pads to be constructed; and provide the electrical connections between the LED chips and external connecting interface. The electrically isolated material will also ensure that the electrical traces will be isolated from the thermally conductive substrate below. By ensuring that the thermally conductive substrate is always electrically isolated, this design easily allows the thermally conductive substrate to be mounted onto a secondary surface for the next level of heat dissipation.

Multiple cavities are formed on the substrate. These cavities are typically molded or injection molded onto the substrate. Suitable materials to form the housing included engineering plastics such as PPA, LCP and high temperature nylon. In addition, thermoset resin and silicone material can also be used to mold the cavities. In order to ensure that these cavities are strongly attached onto the thermally conductive substrate; holes or cut-outs are made on the rear side of the substrate so that molding material can fill into these areas during molding and subsequently become an entity that will lock the cavities onto the substrate. These locks are located on every cavity and do not protrude beyond the rear plane of the thermally conductive substrate. This is important to ensure that no protrusion is allowed on this rear plane that may hamper subsequent mounting to a secondary surface.

Each of these cavities are spaced at regular intervals and the gap between two adjacent cavities are limited to less than 10 mm to ensure that we have a uniform light distribution across the entire module. If the gap is larger, dark spot will be observable in these gaps.

These cavities are used a means to contain the encapsulation material that will be filled into the cavities and provide a seal and protection for the chips from the environment. In addition, the cavity internal wall can also serve as a reflector to improve light extraction for the module. The internal wall can be polished and inclined at an angle to further improve its reflectivity. Metallic coating can also be applied to the walls to achieve close to mirror finish and will further boost the reflectivity. The optical effect due to the internal reflector wall is highly repeatable as the dimension and contour of the walls are very consistent due to the material property and molding process.

LED chips will be mounted within the cavities; on the portion of the thermally conductive substrate that remain clear from the electrically isolated material. The chips can be mounted using epoxy glue, silicone glue or other adhesive material. For even more superior thermal connection, eutectic chip attach or metallic solder can also be used. This construction will ensure superior thermal conductivity as the LED chips are now directly attached to a thermally conductive substrate. In addition, the thermally conductive substrate has a significantly large surface area to easily dissipate heat away.

The encapsulant material used to fill the cavities is typically transparent or diffused epoxy resin systems or silicone. The encapsulant material is easily dispensed into the cavities and subsequently cured under temperature. Luminescence conversion elements such as phosphor may also be added into this encapsulant if certain optical conversion is required. Commonly used luminescence conversion elements include yttrium aluminum gamets (YAG), silicates and nitrides. Other materials such as silica used as diffusant may also be added in order to improve the optical characteristics of the conversion.

FIG. 2 illustrates the cross section view of a typical construction described by the present invention. A thermally conductive substrate (1) is used as the base of the module. Typical materials that can be used include metals such as aluminum, copper and other forms of copper alloy. On top of the thermally conductive substrate, an electrical isolated and thin material (2) is laminated or attached on a portion of the substrate. This isolated material provides a plane for conductive traces to be made. Electrical connections can be made between the LED chips (5) and the traces via electrically conductive wires (6). The LED chips are directly mounted on the thermally conductive substrate. Cavities (3) are formed on the substrate. These cavities are typically molded or injection molded onto the substrate. Suitable materials to form the housing included engineering plastics such as PPA, LCP and high temperature nylon. These cavities are used a means to contain the transparent or diffused encapsulation material (4) that will be filled into the cavities and provide a seal and protection for the LED chips from the environment. The encapsulant material used to fill the cavities is typically epoxy resin systems or silicone. Luminescence conversion elements such as phosphor may also be added into this encapsulant if certain optical conversion is required.

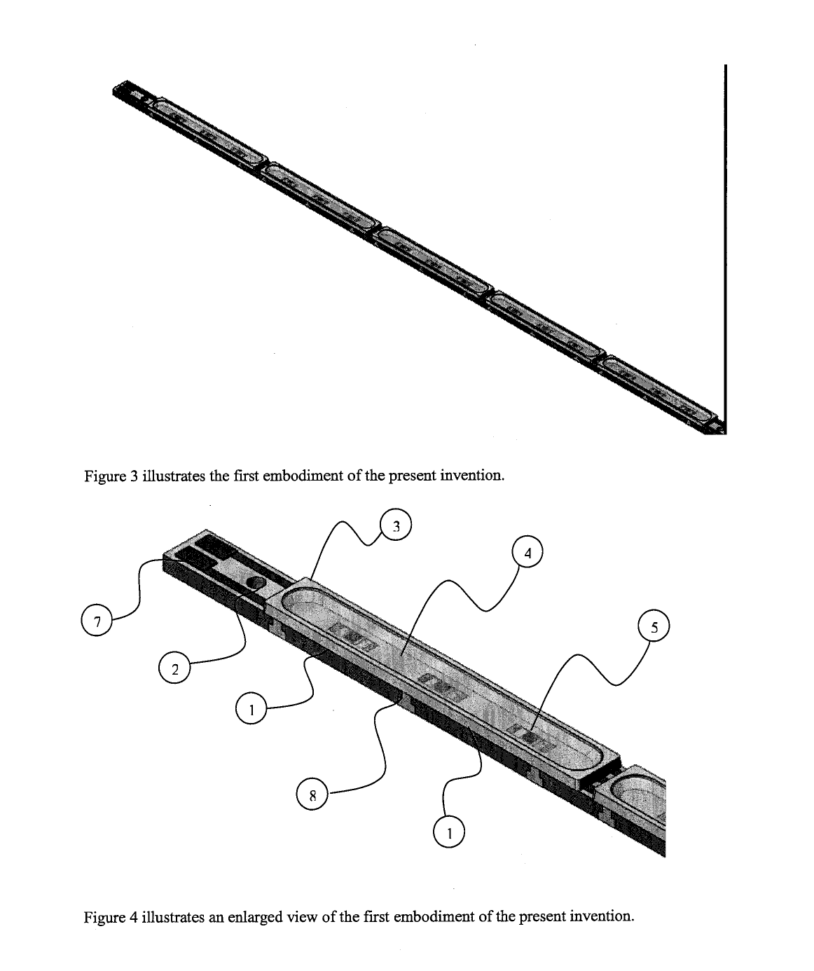

In the first embodiment of the present invention, FIGS. 3 and 4 illustrates a linear lighting module. A thermally conductive substrate (1) is used as the base of the module. Typical materials that can be used include metals such as aluminum, copper and other forms of copper alloy. On top of the thermally conductive substrate, an electrical isolated and thin material (2) is laminated or attached on a portion of the substrate. This electrically isolated material will provide the plane for electrical traces (7) and pads to be constructed; and provide the electrical connections between the LED chips (5) and external connecting interface. Multiple cavities (3) are formed on the substrate. The cavities are spaced linearly with a gap in between two adjacent, cavities of less than 10 mm. These cavities are typically molded or injection molded onto the substrate. Suitable materials to form the housing included engineering plastics such as PPA, LCP and high temperature nylon. In order to ensure that these cavities are strongly attached onto the thermally conductive substrate; holes or cut-outs are made on the rear side of the substrate so that molding material can fill into these areas during molding and subsequently become an entity (8) that will lock the cavities onto the substrate. LED chips (5) are mounted within the cavities. Transparent or diffused encapsulant material (4) is used to fill the cavities. Typical material used as encapsulant includes epoxy resin systems or silicone. Luminescence conversion elements such as phosphor may also be added into this encapsulant if certain optical conversion is required.

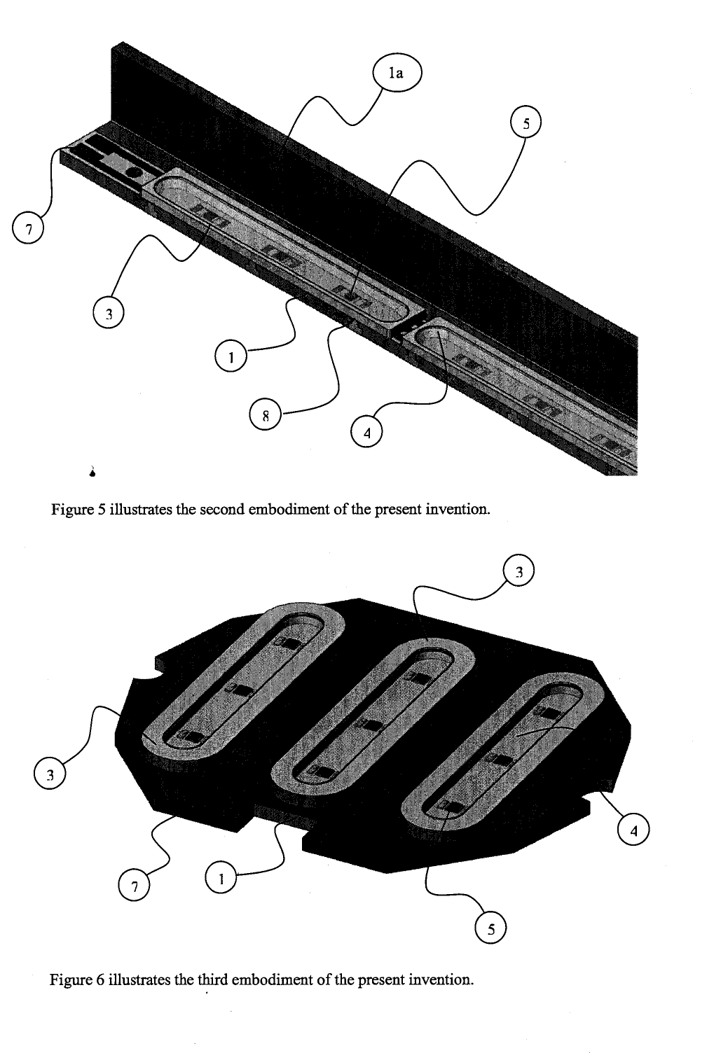

In the second embodiment of the present invention, FIG. 5 illustrates a linear lighting module with and extended structure. A thermally conductive substrate (1) is used as the base of the module. In addition, the substrate is extended in size so that it can be bent into the shape as shown in FIG. 5. The extended substrate (1a) provide for a bigger surface area for better thermal dissipation. This extended substrate can also be used as a mechanical interface surface since the substrate is rigid in nature and mechanically strong. Locating holes or mounting holes can be designed on this extended surface to accommodate for mounting requirements. The thermally conductive nature of the substrate plus the mounting flexibility provides the module with good thermal dissipation capability. Typical material that can be used include metals such as aluminum, copper and other forms of copper alloy. On top of the thermally conductive substrate, an electrical isolated and thin material (2) is laminated or attached on a portion of the substrate. This electrically isolated material will provide the plane for electrical traces (7) and pads to be constructed; and provide the electrical connections between the LED chips (5) and external connecting interface. Multiple cavities (3) are formed on the substrate. The cavities are spaced linearly with a gap in between two adjacent cavities of less than 10 mm. These cavities are typically molded or injection molded onto the substrate. Suitable materials to form the housing included engineering plastics such as PPA, LCP and high temperature nylon. In order to ensure that these cavities are strongly attached onto the thermally conductive substrate; holes or cut-outs are made on the rear side of the substrate so that molding material can fill into these areas during molding and subsequently become an entity (8) that will lock the cavities onto the substrate. LED chips (5) are mounted within the cavities. Transparent or diffused encapsulant material (4) is used to fill the cavities. Typical material used as encapsulant includes epoxy resin systems or silicone. Luminescence conversion elements such as phosphor may also be added into this encapsulant if certain optical conversion is required.

In the third embodiment of the present invention, FIG. 6 illustrates a circular lighting module. A thermally conductive substrate (1) is used as the base of the circular module. Typical materials that can be used include metals such as aluminum, copper and other forms of copper alloy. On top of the thermally conductive substrate, an electrical isolated and thin material (2) is laminated on the substrate. This electrically isolated material will provide the plane for electrical traces (7) and pads to be constructed; and provide the electrical connections between the LED chips (5) and external connecting interface. Multiple cavities (3) are formed on the substrate and are positioned close together. The cavities are spaced with a gap in between two adjacent cavities of less than 10 mm. These cavities are typically molded or injection molded onto the substrate. Suitable materials to form the housing included engineering plastics such as PPA, LCP and high temperature nylon. LED chips (5) are mounted within the cavities. A transparent or diffused encapsulant material (4) is used to fill the cavities. Typical material used as encapsulant includes epoxy resin systems or silicone. Luminescence conversion elements such as phosphor may also be added into this encapsulant if certain optical conversion is required.

1. A light emitting diode (LED) module that is characterized by a thermally conductive substrate which is used as the base of the module; a plurality of cavities positioned on the module; each cavity is filled with a transparent or diffused encapsulant material and a plurality of LED semiconductors chips are mounted within each cavity.

2. A light emitting diode (LED) module as stated in claim 1, where the LED chips are directly attached to the thermally conductive substrate that is used as the base of the module.

3. A light emitting diode (LED) module as stated in claim 1, where the thermally conductive substrate will serve as the heat-sink for the module.

4. A light emitting diode (LED) module as stated in claim 1, where the thermally conductive substrate is extended and is formed and bent to provide better heat dissipation and mounting surface.

5. A light emitting diode (LED) module as stated in claim 1, where holes or cut-outs are made on the rear side of the thermally conductive substrate so that molding material can fill into these areas and become an entity that will lock the cavities onto the substrate.

6. A light emitting diode (LED) module as stated in claim 1, where the cavities are spaced and the gap between two adjacent cavities is less than 10 mm.
